(19) United States
(12) Patent Application Publication
(10) Pub. No.: US 2026/0254448 A1
(43) Pub. Date: Aug. 27, 2026

(54) SEMICONDUCTOR DEVICE AND OPERATING METHOD THEREOF

(71) Applicant: TAIWAN SEMICONDUCTOR MANUFACTURING COMPANY, LTD., Hsinchu (TW)

(72) Inventors: Shih Jie HUANG, Taichung City (TW); Yi-Hsiang WANG, New Taipei City (TW); Szu-Chun TSAO, Hsinchu City (TW)

(73) Assignee: TAIWAN SEMICONDUCTOR MANUFACTURING COMPANY, LTD., Hsinchu (TW)

(21) Appl. No.: 19/064,378

(22) Filed: Feb. 26, 2025

(51) Int. Cl. H03K 17/0812

(52) U.S. Cl. CPC H03K 17/08122

(57) ABSTRACT

A semiconductor device, comprises a first switch circuit configured to receive an input voltage signal and provide a first output voltage signal to a circuit; a first control circuit coupled to the first switch circuit, configured to turn on the first switch circuit when the input voltage signal has a first voltage level, and configured to turn off the first switch circuit when the input voltage signal has a second voltage level; a second switch circuit configured to receive the input voltage signal and provide a second output voltage signal to the circuit; and a second control circuit coupled to the second switch circuit, configured to turn on the second switch when the input voltage has the second voltage level, and turn off the second switch when the input voltage has the first voltage level, wherein the first voltage level is different from the second voltage level.

### BACKGROUND

A semiconductor device includes a core device and an input/output device. The core device is configured to perform computing operation. The input/output device is configured to transmit the power to the core device. During operation, the input/output device tolerates multiple voltage differences. However, the core device tolerates voltage differences in a certain range which cause a reliability issue of the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a semiconductor device, illustrated in accordance with some embodiments of the presented disclosure.

FIG. 2A is a circuit diagram of a first switch circuit of the semiconductor device, illustrated in accordance with some embodiments of the presented disclosure.

FIG. 2B is a circuit diagram of a second switch circuit of the semiconductor device, illustrated in accordance with some embodiments of the presented disclosure.

FIG. 3A is a circuit diagram of a control circuit of the semiconductor device, illustrated in accordance with some embodiments of the presented disclosure.

FIG. 3B is a table of the signals associated with the control circuit, illustrated in accordance with some embodiments of the presented disclosure.

FIG. 4A is a circuit diagram of further details of a part of the semiconductor device, illustrated in accordance with some embodiments of the presented disclosure.

FIG. 4B is a circuit diagram of further details of a part of the semiconductor device, illustrated in accordance with some embodiments of the presented disclosure.

FIG. 5A is a table of voltage differences of the switch circuit shown in FIG. 2A, illustrated in accordance with some embodiments of the presented disclosure.

FIG. 5B is a table of voltage differences of the switch circuit shown in FIG. 2B, illustrated in accordance with some embodiments of the presented disclosure.

FIG. 5C is a table of voltage differences of the switch circuit shown in FIG. 2A, illustrated in accordance with some embodiments of the presented disclosure.

FIG. 5D is a table of voltage differences of the switch circuit shown in FIG. 2A, illustrated in accordance with some embodiments of the presented disclosure.

FIG. 6A is a layout structure of the switch circuits illustrated in accordance with some embodiments of the presented disclosure.

FIG. 6B is a layout structure of the switch circuits illustrated in accordance with some embodiments of the presented disclosure.

FIG. 7 is a schematic view of a system for designing and manufacturing at least one of the semiconductor devices described herein, illustrated in accordance with some embodiments of the presented disclosure.

FIG. 8 is a block diagram of an integrated circuit (IC)/semiconductor device manufacturing system, and an IC manufacturing flow associated therewith, illustrated in accordance with some embodiments of the presented disclosure.

FIG. 9 is a flow diagram of a method of operating the semiconductor device illustrated in accordance with some embodiments of the presented disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

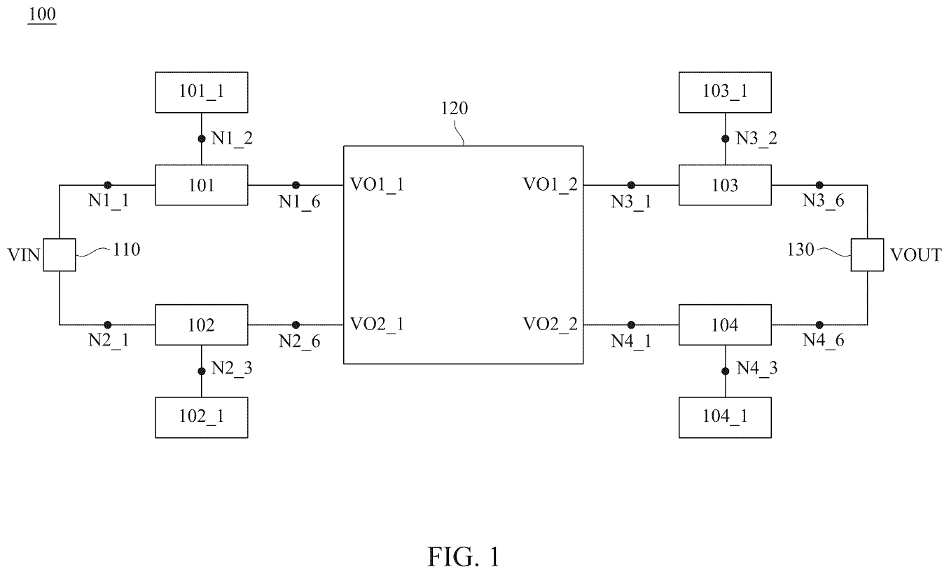

FIG. 1 is a schematic diagram of a semiconductor device 100, illustrated in accordance with some embodiments of the presented disclosure. As illustratively shown in FIG. 1, the semiconductor device 100 includes a power circuit 110, a testing circuit 120, an output circuit 130, switch circuits 101-104, and control circuits 101_1-101_4.

In some embodiments, the power circuit 110 is configured to provide an input voltage signal VIN to the switch circuit 101 through a node N1_1, and provide the input voltage signal VIN to the switch circuit 102 through a node N2_1. The control circuit 101_1 is coupled to the switch circuit 101 through a node N1_2, and configured to control the switch circuit 101 according to the input voltage signal VIN. The control circuit 102_1 is coupled to the switch circuit 102 through a node N2_3, and is configured to control the switch circuit 102 according to the input voltage signal VIN. The switch circuit 101 is configured to generate the output voltage signal VO1_1 to the testing circuit 120 through a node N1_6. The switch circuit 102 is configured to generate the output voltage signal VO2_1 to the testing circuit 120 through a node N2_6. In some embodiments, the testing circuit 120 is configured to generate output voltage signals VO1_2 and VO2_2 according to the VO1_1 and VO2_1, respectively.

In some embodiments, the switch circuit 103 is configured to receive the VO1_2 through N3_1, and generate an output voltage signal VOUT at a node N3_6. The switch circuit 104 is configured to receive the VO2_2 through N4_1, and generate the output voltage signal VOUT at a node N4_6. The output circuit 130 is configured to receive the output voltage signal VOUT from the switch circuits 103 and 104. The control circuit 103_1 is coupled to the switch circuit 103 through a node N3_2, and is configured to control the switch circuit 103 according to the input voltage signal VIN. The control circuit 104_1 is coupled to the switch circuit 104 through a node N4_3, and is configured to control the switch circuit 104 according to the input voltage signal VIN. In some embodiments, the switch circuits 103 and 104 are configured to provide the output voltage signal VOUT to the output circuit 130 through nodes N3_6 and N4_6, respectively.

In some embodiments, the testing circuit 120 is implemented by a core device in practical application. For example, core device includes but not limited to Central Processing Unit (CPU), Micro Processing Unit (MPU), Micro Control Unit (MCU), or other similar processing unit. In some embodiments, the power circuit 110 is implemented by a conductive line coupled to a pad.

In some embodiments, the testing circuit 120 is configured to perform computation according to the input voltage signal VIN, and generate the computation result in a form of the output voltage signals VO1_2 and VO2_2.

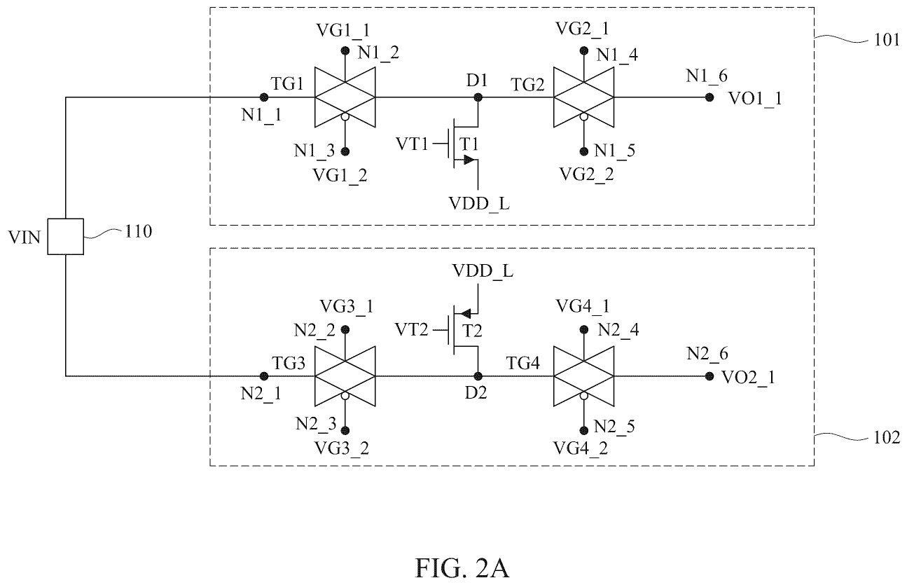

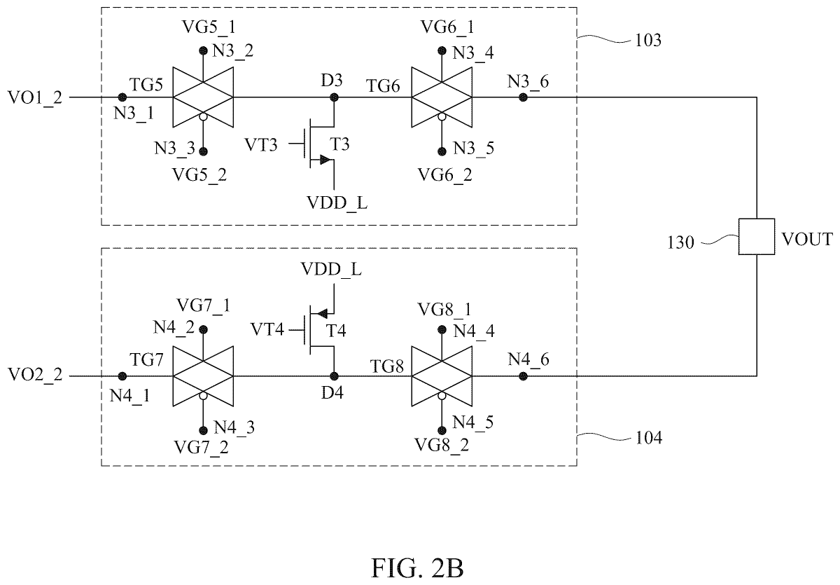

FIG. 2A is a circuit diagram of the switch circuits 101 and 102 of the semiconductor device 100, illustrated in accordance with some embodiments of the presented disclosure. As shown in FIG. 2A, the switch circuit 101 includes switch elements TG1, TG2, and T1. The switch circuit 102 includes switch elements TG3, TG4, and T2.

As illustratively shown in FIG. 2A, a first terminal of the switch element TG1 is coupled to the power circuit 110 at the node N1_1, and is configured to receive the input voltage signal VIN. A first terminal of the switch element TG3 is coupled to the power circuit 110 at the node N2_1, and is configured to receive the input voltage signal VIN. A second terminal of the switch element TG1 is coupled to a first terminal of the switch element TG2 through a node D1. A second terminal of the switch element TG3 is coupled to a first terminal of the switch element TG4 through a node D2. A second terminal of the switch element TG2 is coupled to the testing circuit 120 through the node N1_6, and is configured to generate the output voltage signal VO1_1 to the testing circuit 120. A second terminal of the switch element TG4 is coupled to the testing circuit 120 through the node N2_6, and is configured to generate the output voltage signal VO2_1 to the testing circuit 120.

In some embodiment, a first control terminal of the switch element TG1 is configured to receive a voltage signal VG1_1 at the node N1_2. A second control terminal of the switch element TG1 is configured to receive a voltage signal VG1_2 at the node N1_3. A first control terminal of the switch element TG2 is configured to receive a voltage signal VG2_1 at the node N1_4. A second control terminal of the switch element TG2 is configured to receive a voltage signal VG2_2 at the node N1_5. A first control terminal of the switch element TG3 is configured to receive a voltage signal VG3_1 at the node N2_2. A second control terminal of the switch element TG3 is configured to receive a voltage signal VG3_2 at the node N2_3. A first control terminal of the switch element TG4 is configured to receive a voltage signal VG4_1 at the node N2_4. A second control terminal of the switch element TG4 is configured to receive a voltage signal VG4_2 at the node N2_5.

In some embodiments, the switch element T1 is configured to adjust a node voltage signal VD1 at the node D1. A first terminal of the switch element T1 is coupled to the node D1. A second terminal of the switch element T1 is configured to receive a voltage signal VDD_L. A control terminal of the switch element T1 is configured to receive a voltage signal VT1. In some embodiments, the voltage signal VDD_L has a voltage level VL. The switch element T1 is turned on when the voltage signal VT1 has a voltage level VH, and is turned off then the voltage signal VT1 has the voltage level VL. When the switch element T1 is turned on, the voltage signal VDD_L is transmitted to the node D1, such that the node voltage signal VD1 has the voltage level VL.

In some embodiments, the switch element T2 is configured to adjust a node voltage signal VD2 at the node D2. A first terminal of the switch element T2 is coupled to the node D2. A second terminal of the switch element T2 is configured to receive the voltage signal VDD_L. A control terminal of the switch element T2 is configured to receive a voltage signal VT2. The switch element T2 is turned on when the voltage signal VT2 has a ground voltage level, and is turned off then the voltage signal VT2 has the voltage level VL. When the switch element T2 is turned on, the voltage signal VDD_L is transmitted to the node D2, such that the node voltage signal VD2 has the voltage level VL.

In some embodiments, each of the switch elements TG1, TG2, TG3 and TG4 is implemented by a transmission gate. In some embodiments, the switch element T1 is implemented by a transistor of a first conductive type, such as an N-type transistor. In some embodiments, the switch element T2 is implemented by a transistor of a second conductive type, such as a P-type transistor. However, the presented disclosure is not limited to this. In various embodiments, the switch elements TG1, TG2, TG3, TG4, T1, and T2 are implemented by various types of elements.

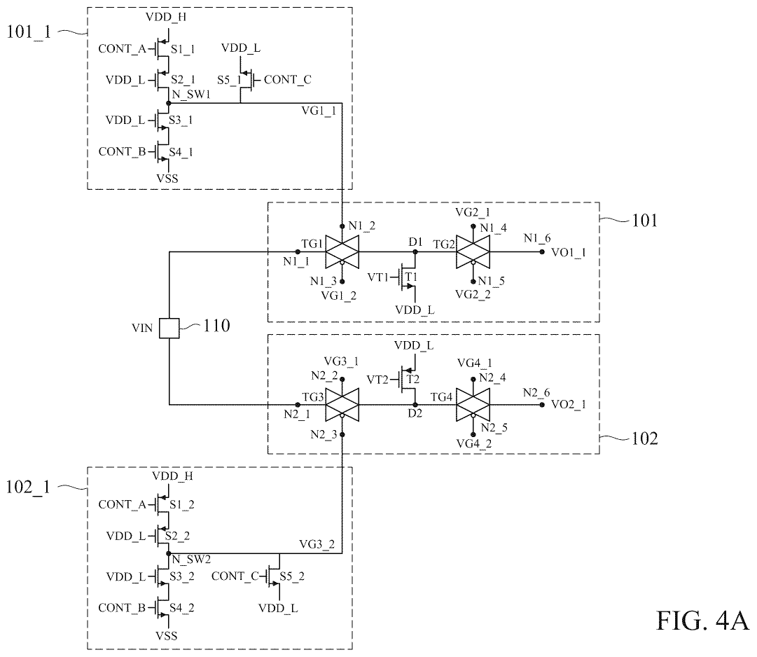

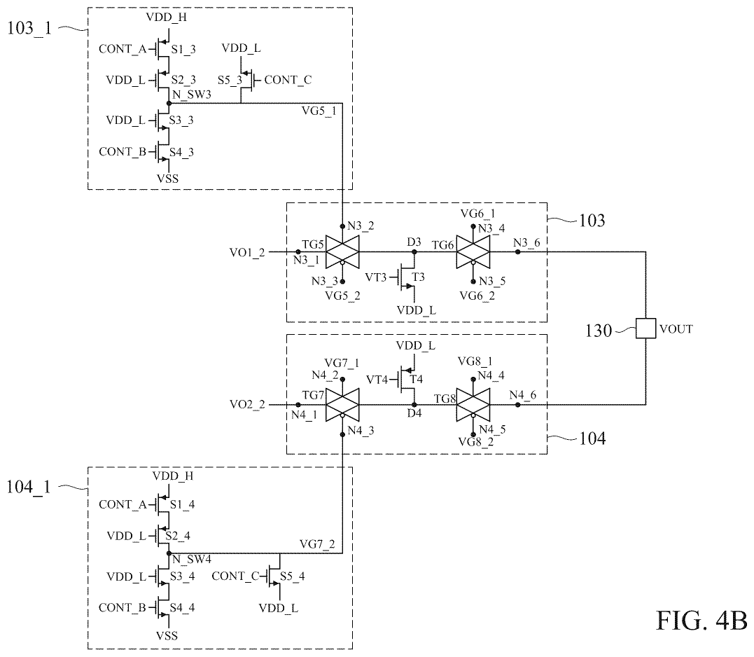

In some embodiments, the switch circuits 101 and 102 operate in response to different voltage levels of the input voltage signal VIN. When the input voltage signal VIN has the voltage level VH, the switch circuit 101 is turned on to provide a conductive path from the power circuit 110 to the node N1_6, and the switch circuit 102 is turned off. When the input voltage signal VIN has a voltage level VL, the switch circuit 102 is turned on to provide a conductive path from the power circuit 110 to the node N2_6, and the switch circuit 101 is turned off. Further details regarding the voltage levels VL, VH and the operations of the switch circuits 101 and 102 are described below with the embodiments associated with FIG. 4A.

FIG. 2B is a circuit diagram of the switch circuits 103 and 104 of the semiconductor device 100, illustrated in accordance with some embodiments of the presented disclosure. As shown in FIG. 2B, the switch circuit 103 includes switch elements TG5, TG6, and T3. The switch circuit 104 includes switch elements TG7, TG8, and T4.

As illustratively shown in FIG. 2B, a first terminal of the switch element TG5 is coupled to the testing circuit 120 at the node N3_1, and is configured to receive the output voltage signal VO1_2. A first terminal of the switch element TG7 is coupled to the testing circuit 110 at the node N4_1, and is configured to receive the output voltage signal VO2_2. A second terminal of the switch element TG5 is coupled to a first terminal of the switch element TG6 through a node D3. A second terminal of the switch element TG7 is coupled to a first terminal of the switch element TG8 through a node D4. A second terminal of the switch element TG6 is coupled to the output circuit 130 through the node N3_6, and is configured to generate the output voltage signal VOUT to the output circuit 130. A second terminal of the switch element TG8 is coupled to the output circuit 130 through the node N4_6, and is configured to generate the output voltage signal VOUT to the output circuit 130.

In some embodiment, a first control terminal of the switch element TG5 is configured to receive a voltage signal VG5_1 at the node N3_2. A second control terminal of the switch element TG5 is configured to receive a voltage signal VG5_2 at the node N3_3. A first control terminal of the switch element TG6 is configured to receive a voltage signal VG6_1 at the node N3_4. A second control terminal of the switch element TG6 is configured to receive a voltage signal VG6_2 at the node N3_5. A first control terminal of the switch element TG7 is configured to receive a voltage signal VG7_1 at the node N4_2. A second control terminal of the switch element TG7 is configured to receive a voltage signal VG7_2 at the node N4_3. A first control terminal of the switch element TG8 is configured to receive a voltage signal VG8_1 at the node N4_4. A second control terminal of the switch element TG8 is configured to receive a voltage signal VG8_2 at the node N4_5.

In some embodiments, the switch element T3 is configured to adjust a node voltage signal VD3 at the node D3. A first terminal of the switch element T3 is coupled to the node D3. A second terminal of the switch element T3 is configured to receive a voltage signal VDD_L. A control terminal of the switch element T3 is configured to receive a voltage signal VT3. In some embodiments, the voltage signal VDD_L has a voltage level VL. The switch element T3 is turned on when the voltage signal VT3 has the voltage level VH, and is turned off then the voltage signal VT3 has the voltage level VL. When the switch element T3 is turned on, the voltage signal VDD_L is transmitted to the node D3, such that the node voltage signal VD3 has the voltage level VL.

In some embodiments, the switch element T4 is configured to adjust a node voltage signal VD4 at the node D4. A first terminal of the switch element T4 is coupled to the node D4. A second terminal of the switch element T4 is configured to receive a voltage signal VDD_L. A control terminal of the switch element T4 is configured to receive a voltage signal VT4. The switch element T4 is turned on when the voltage signal VT4 has a ground voltage level, and is turned off then the voltage signal VT4 has the voltage level VL. When the switch element T4 is turned on, the voltage signal VDD_L is transmitted to the node D4, such that the node voltage signal VD4 has the voltage level VL.

In some embodiments, each of the switch elements TG5, TG6, TG7 and TG8 is implemented by a transmission gate. In some embodiments, the switch element T3 is implemented by a transistor of a first conductive type, such as an N-type transistor. In some embodiments, the switch element T4 is implemented by a transistor of a second conductive type, such as a P-type transistor. However, the presented disclosure is not limited to this. In various embodiments, the switch elements TG5, TG6, TG7, TG8, T3, and T4 are implemented by various types of elements.

In some embodiments, the switch circuits 103 and 104 operate in response to different voltage levels of the input voltage signal VIN. When the input voltage signal VIN has the voltage level VH, the switch circuit 103 is turned on to provide a conductive path from the testing circuit 120 to the node N3_6, and the switch circuit 104 is turned off. When the input voltage signal VIN has the voltage level VL, the switch circuit 104 is turned on to provide a conductive path from the testing circuit 120 to the node N4_6, and the switch circuit 103 is turned off. Further details regarding the operations of the switch circuits 103 and 104 are described below with the embodiments associated with FIG. 4B.

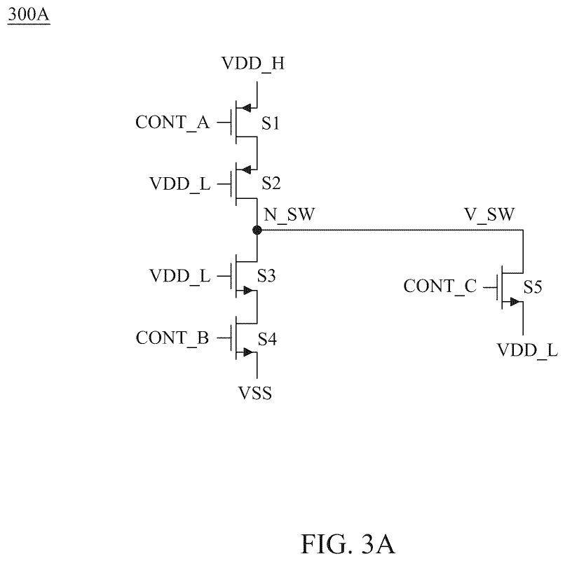

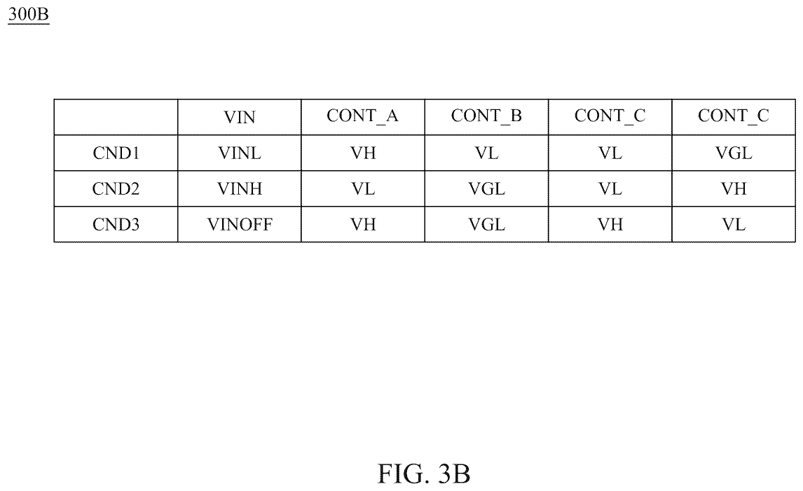

FIG. 3A is a circuit diagram of a control circuit 300A of the semiconductor device 100, illustrated in accordance with some embodiments of the presented disclosure. Referring to FIG. 3A and FIG. 1, in some embodiments at least one of configurations of the control circuits 101_1, 102_1, 103_1, and 104_1 is similar with the configuration of the control circuit 300A.

As illustratively shown in FIG. 3A, the control circuit 300A includes switch elements S1-S5. A first terminal of the switch element S1 is configured to receive a voltage signal VDD_H, a second terminal of the switch element S1 is coupled to a first terminal of the switch element S2. A second terminal of the switch element S2 is coupled to a first terminal of the switch element S3 at a node N_SW. A second terminal of the switch element S3 is coupled to a first terminal of the switch element S4. A second terminal of the switch element S4 is configured to receive a reference voltage signal VSS. A first terminal of the switch element S5 is coupled to each of the switch elements S2 and S3 at the node N_SW. A second terminal of the switch element S5 is configured to receive the voltage signal VDD_L.

In some embodiments, the reference voltage signal VSS has a voltage level VGL. The reference voltage signal VDD_H has a voltage level VH, and the voltage signal VDD_L has the voltage level VL. In some embodiments, the voltage level VH is higher than the voltage level VL, and the voltage level VL is higher than the voltage level VGL. In some embodiments, the voltage level VGL is a ground voltage level.

In some embodiments, a control terminal of the switch element S1 is configured to receive a control signal CONT_A. A control terminal of the switch element S2 is configured to receive the voltage signal VDD_L. A control terminal of the switch element S3 is configured to receive the voltage signal VDD_L. A control terminal of the switch element S4 is configured to receive a control signal CONT_B. A control terminal of the switch element S5 is configured to receive a control signal CONT_C.

In some embodiments, each of the switch elements S2 and S3 is turned on in response to the corresponding control terminals having the voltage level VL. Accordingly, the switch element S1 is electrically coupled to the node N_SW through the switch element S2. The switch element S4 is electrically coupled to the node N_SW through the switch element S3. In some embodiments, the switch elements S2 and S3 are configured to provide a high voltage protection for the node N_SW.

In some embodiments, each of the switch elements S3, S4, and S5 is implemented by a transistor of a first conductive type, such as an N-type transistor. Each of the switch elements S1 and S2 is implemented by a transistor of a second conductive type, such as a P-type transistor. In various embodiments, the switch elements S1-S5 are implemented by various types of elements.

In some embodiments, each of the control signals CONT_A, CONT_B, and CONT_C is provided by a system controller (not shown) based on the input voltage signal VIN. The control circuit 300A is configured to generate a voltage signal V_SW at the N_SW based on the control signals CONT_A, CONT_B, and CONT_C. Alternatively stated, the control circuit 300A is configured to generate the voltage signal V_SW based on the input voltage signal VIN.

FIG. 3B is a table 300B of the signals associated with the control circuit 300A, illustrated in accordance with some embodiments of the presented disclosure. The table 300B shows voltage levels of the control signals CONT_A, CONT_B, and CONT_C and the voltage signal V_SW in conditions CND1, CND2, and CND3.

In the condition CND1, the input voltage signal VIN has the voltage level VINL. The voltage level VINL is between the voltage level VGL and the voltage level VL. In the condition CND2, the input voltage signal VIN has the voltage level VINH. The voltage level VINH is between the voltage level VL and the voltage level VH. In the condition CND3, the input voltage signal VIN has the voltage level VINOFF. The voltage level VINOFF is between the voltage level VGL and the voltage level VH.

In some embodiments, the voltage level VGL is equal to 0 volt, the voltage level VL is equal to 0.75 volt, and the voltage level VH is equal to 1.5 volt. However, the presented disclosure is not limit to the values of the voltage levels above.

In some embodiments, the switch element S1 is configured to be turned on when the control signal CONT_A has the voltage level VL, and is configured to turn off when the control signal CONT_A has the voltage level VH. The switch element S4 is configured to be turned on when the control signal CONT_B has the voltage level VL, and is configured to turn off when the control signal CONT_B has the voltage level VGL. The switch element S5 is configured to be turned on when the control signal CONT_C has the voltage level VH, and is configured to turn off when the control signal CONT_C has the voltage level VL.

Referring to FIGS. 3A and 3B, in the condition CND1, the control signal CONT_A has the voltage level VH, such that the switch element S1 is turned off. The control signal CONT_B has the voltage level VL, such that the switch element S4 is turned on. The control signal CONT_C has the voltage level VL, such that the switch element S5 is turned off. Accordingly, the switch element S4 transmits the voltage signal VSS to the node N_SW, such that the voltage signal V_SW has the voltage level VGL.

In the condition CND2, the control signal CONT_A has the voltage level VL, such that the switch element S1 is turned on. The control signal CONT_B has the voltage level VGL, such that the switch element S4 is turned off. The control signal CONT_C has the voltage level VL, such that the switch element S5 is turned off. Accordingly, the switch element S4 transmits the voltage signal VSS to the node N_SW, such that the voltage signal V_SW has the voltage level VH.

In the condition CND3, the control signal CONT_A has the voltage level VH, such that the switch element S1 is turned off. The control signal CONT_B has the voltage level VGL, such that the switch element S4 is turned off. The control signal CONT_C has the voltage level VH, such that the switch element S5 is turned on. Accordingly, the switch element S4 transmits the voltage signal VSS to the node N_SW, such that the voltage signal V_SW has the voltage level VL.

In some embodiments, the voltage signal V_SW corresponds to each of the voltage signals VG1_1, VG3_2, VG5_1, and VG7_2 shown in FIGS. 4A-4B. Further details regarding the voltage signals VG1_1, VG3_2, VG5_1, and VG7_2 are discussed in FIGS. 4A-4B and the corresponding paragraph.

FIG. 4A is a circuit diagram of further details of a part of the semiconductor device 100, illustrated in accordance with some embodiments of the presented disclosure.

As illustratively shown in FIG. 4A, the control circuit 101_1 includes switch elements S1_1, S2_1, S3_1, S4_1, and S5_1. A first terminal of the switch element S1_1 is configured to receive a voltage signal VDD_H, a second terminal of the switch element S1_1 is coupled to a first terminal of the switch element S2_1. A second terminal of the switch element S2_1 is coupled to a first terminal of the switch element S3_1 at a node N_SW1. A second terminal of the switch element S3_1 is coupled to a first terminal of the switch element S4_1. A second terminal of the switch element S4_1 is configured to receive the reference voltage signal VSS. A first terminal of the switch element S5_1 is coupled to each of the switch elements S2_1 and S3_1 at the node N_SW1. A second terminal of the switch element S5_1 is configured to receive the voltage signal VDD_L. The control circuit 101_1 is configured to transmit the

### Voltage Signal Vg1_1 to the Node N1_2.

In some embodiments, a control terminal of the switch element S1_1 is configured to receive the control signal CONT_A. A control terminal of the switch element S2_1 is configured to receive the voltage signal VDD_L. A control terminal of the switch element S3_1 is configured to receive the voltage signal VDD_L. A control terminal of the switch element S4_1 is configured to receive the control signal CONT_B. A control terminal of the switch element S5_1 is configured to receive the control signal CONT_C.

As illustratively shown in FIG. 4A, the control circuit 102_1 includes switch elements S1_2, S2_2, S3_2, S4_2, and S5_2. A first terminal of the switch element S1_2 is configured to receive a voltage signal VDD_H, a second terminal of the switch element S1_2 is coupled to a first terminal of the switch element S2_2. A second terminal of the switch element S2_2 is coupled to a first terminal of the switch element S3_2 at a node N_SW2. A second terminal of the switch element S3_2 is coupled to a first terminal of the switch element S4_2. A second terminal of the switch element S4_2 is configured to receive the reference voltage signal VSS. A first terminal of the switch element S5_2 is coupled to each of the switch elements S2_2 and S3_2 at the node N_SW2. A second terminal of the switch element S5_2 is configured to receive the voltage signal VDD_L. The control circuit 102_1 is configured to transmit the voltage signal VG3_2 to the node N2_3.

In some embodiments, a control terminal of the switch element S1_2 is configured to receive the control signal CONT_A. A control terminal of the switch element S2_2 is configured to receive the voltage signal VDD_L. A control terminal of the switch element S3_2 is configured to receive the voltage signal VDD_L. A control terminal of the switch element S4_2 is configured to receive the control signal CONT_B. A control terminal of the switch element S5_2 is configured to receive the control signal CONT_C.

In some embodiments, the switch element TG1 is turned off when the voltage signal VG1_1 has the voltage level VGL, and is turned on when the VG1_1 has the voltage level VH. The switch element TG3 is turned off when the voltage signal VG3_2 has the voltage level VH, and is turned on when the VG3_2 has the voltage level VGL.

Referring to FIG. 3A to FIG. 4A, in condition CND1, the switch element S4_1 is turned on to adjust the voltage signal VG1_1 to the voltage level VGL, such that the switch element TG1 is turned off. On the other hand, the switch element S4_2 is turned on to adjust the voltage signal VG3_2 to have the voltage level VGL, such that the switch element TG3 is turned on.

In some embodiments, the switch element T1 is configured to reduce the voltage difference VG_d1 between the nodes N1_1 and D1, and is configured to reduce the voltage difference VG_d2 between the nodes D1 and N1_6. When the switch circuit 101 is turned off, the input voltage signal VIN is terminated at the node N1_1. At this moment, each of a voltage differences VG_d1 and VG_d2 has a voltage level lower than the voltage level VL. When the switch circuit 101 is turned off, each of the voltage signals VG1_2 and VG2_1 has the voltage level VL, and the voltage signal VG2_2 has the voltage level VH. The switch element T1 is turned on by receiving the voltage signal VT1 having the voltage level VH. In response to the switch element T1 being turned on, the node voltage signal VD1 has the voltage level VL.

On the other hand, in condition CND1, the switch circuit 102 is turned on, such that the power circuit 110 provides the input voltage signal VIN to the switch element TG3 through the node N2_1. The switch element TG3 transmits the input voltage signal VIN through the switch element TG4 to generate the output voltage signal VO2_1 at the node N2_6. The testing circuit 120 is configured to receive the output voltage signal VO2_1 from the node N2_6 and generate the output voltage signals VO1_2 and VO2_2 to the nodes N3_1 and N4_1, respectively.

In some embodiments, in response to the switch circuit 102 being turned on, each of the voltage signals VG3_1 and VG4_1 has the voltage level VL, and the voltage signal VG4_2 has the voltage level VGL. At this moment, the circuit element T2 is turned off by receiving the voltage signal VT2 having the voltage level VL.

Referring to FIG. 3A to FIG. 4A, in condition CND2, the voltage signal VG1_1 having the voltage level VH is transmitted to the switch element TG1, such that the switch circuit 101 is turned on to receive the input voltage signal VIN. On the other hand, the voltages signal VG3_2 having the voltage level VH is transmitted to the switch element TG3, such that the switch circuit 102 is turned off.

In some embodiments, the switch element T1 is configured to reduce the voltage difference VG_d3 between the nodes N2_1 and D2, and is configured to reduce the voltage difference VG_d4 between the nodes D2 and N2_6. When the switch circuit 102 is turned off, the input voltage signal VIN is terminated at the node N1_1. At this moment, each of the voltage differences VG_d3 and VG_d4 has a voltage level lower than a difference between the voltage levels VH and VL. When the switch circuit 102 is turned off, each of the voltage signals VG3_1, VG4_1 and VG4_2 has the voltage level VL. The voltage signal VT2 has the voltage level VGL, such that the switch element T2 is turned on. In response to the switch element T2 being turned on, the node voltage signal VD2 has the voltage level VL.

On the other hand, in condition CND2, the switch circuit 101 is turned on, such that the power circuit 110 provides the input voltage signal VIN to the switch element TG1 through the node N1_1. The switch element TG1 transmits the input voltage signal VIN through the switch element TG2 to generate the output voltage signal VO1_1 at the node N1_6. The testing circuit 120 is configured to receive the output voltage signal VO1_1 from the node N1_6 and generate the output voltage signals VO1_2 and VO2_2 to the nodes N3_1 and N4_1, respectively.

In some embodiments, in response to the switch circuit 101 is turned on, each of the voltage signals VG1_2 and VG2_2 has the voltage level VL, and the voltage signal VG2_1 has the voltage level VH. At this moment, the circuit element T1 is turned off by receiving the voltage signal VT2 having the voltage level VL.

Referring to FIG. 3A to FIG. 4A, in condition CND3, the control circuit 101_1 transmits the voltage signal VG1_1 having the voltage level VL to the switch element TG1, such that the switch circuit 101 is turned off. The control circuit 102_1 transmits the voltage signal VG3_2 having the voltage level VL to the switch element TG3, such that the switch circuit 102 is turned off. At this moment, in response to each of the switch circuits 101 and 102 is turned off, the input voltage signal VIN is terminated at each of the nodes N1_1 and N2_1. In some embodiments, the condition CND3 is referred as a turn off operation of the semiconductor device 100.

In some embodiments, when the voltage level VINOFF of the input voltage signal VIN is lower than a threshold voltage level VTH, each of the voltage differences VG_d1, VG_d3 and VG_d4 has a voltage level lower than the voltage level VL. The voltage difference VG_d2 has a voltage level lower than a voltage level of subtracting the voltage level VH by the voltage level VL.

In some other embodiments, when the voltage level VINOFF of the input voltage signal VIN is higher than the threshold voltage level VTH, each of the voltage differences VG_d1, VG_d2, VG_d3 and VG_d4 has a voltage level lower than a voltage level of subtracting the voltage level VH by the voltage level VL.

In some approaches, a switch circuit provides voltage signal to a testing circuit. However, voltage differences between nodes of the switch circuit are high. As a result, when the testing circuit is replaced by a core device, the core device and switch elements in the switch circuit are damaged by those high voltage differences.

Compared to above approaches, in some embodiments of presented disclosure, the switch element T1 is turned on to secure that each of the voltage differences VG_d1 and VG_d2 has a voltage level lower than the voltage level VL. The switch element T2 is turned on to secure that each of the voltage differences VG_d3 and VG_d4 has a voltage level lower than the difference between the voltage levels VH and VL. Accordingly, voltage levels of the output voltage signals VO1_1 and VO2_1 provided by the switch circuits 101 and 102 respectively are low. As a result, when the testing circuit 120 is replaced by a core device, the core device and the switch elements TG1, TG2, TG3, and TG4 are protected by those low voltage differences.

FIG. 4B is a circuit diagram of further details of another part of the semiconductor device 100, illustrated in accordance with some embodiments of the presented disclosure.

As illustratively shown in FIG. 4B, the control circuit 103_1 includes switch elements S1_3, S2_3, S3_3, S4_3, and S5_3. A first terminal of the switch element S1_3 is configured to receive the voltage signal VDD_H, a second terminal of the switch element S1_3 is coupled to a first terminal of the switch element S2_3. A second terminal of the switch element S2_3 is coupled to a first terminal of the switch element S3_3 at a node N_SW3. A second terminal of the switch element S3_3 is coupled to a first terminal of the switch element S4_3. A second terminal of the switch element S4_3 is configured to receive the reference voltage signal VSS. A first terminal of the switch element S5_3 is coupled to each of the switch elements S2_3 and S3_3 at the node N_SW1. A second terminal of the switch element S5_3 is configured to receive the voltage signal VDD_L. The control circuit 103_1 is configured to transmit the voltage signal VG5_1 to the node N3_2.

In some embodiments, a control terminal of the switch element S1_3 is configured to receive the control signal CONT_A. A control terminal of the switch element S2_3 is configured to receive the voltage signal VDD_L. A control terminal of the switch element S3_3 is configured to receive the voltage signal VDD_L. A control terminal of the switch element S4_3 is configured to receive the control signal CONT_B. A control terminal of the switch element S5_3 is configured to receive the control signal CONT_C.

As illustratively shown in FIG. 4B, the control circuit 104_1 includes switch elements S1_4, S2_4, S3_4, S4_4, and S5_4. A first terminal of the switch element S1_4 is configured to receive a voltage signal VDD_H, a second terminal of the switch element S1_4 is coupled to a first terminal of the switch element S2_4. A second terminal of the switch element S2_4 is coupled to a first terminal of the switch element S3_4 at a node N_SW4. A second terminal of the switch element S3_2 is coupled to a first terminal of the switch element S4_4. A second terminal of the switch element S4_4 is configured to receive the reference voltage signal VSS. A first terminal of the switch element S5_4 is coupled to each of the switch elements S2_4 and S3_4 at the node N_SW4. A second terminal of the switch element S5_4 is configured to receive the voltage signal VDD_L. The control circuit 104_1 is configured to transmit the voltage signal VG7_2 to the node N4_3.

In some embodiments, a control terminal of the switch element S1_4 is configured to receive a control signal CONT_A. A control terminal of the switch element S2_4 is configured to receive the voltage signal VDD_L. A control terminal of the switch element S3_4 is configured to receive the voltage signal VDD_L. A control terminal of the switch element S4_4 is configured to receive a control signal CONT_B. A control terminal of the switch element S5_4 is configured to receive a control signal CONT_C.

In some embodiments, the switch element TG5 is turned off when the voltage signal VG5_1 has the voltage level VGL, and is turned on when the VG5_1 has the voltage level VH. The switch element TG7 is turned off when the voltage signal VG7_2 has the voltage level VH, and is turned on when the VG7_2 has the voltage level VGL.

Referring to FIG. 3A to FIG. 4B, in condition CND1, the voltage signal VG5_1 having the voltage level VGL is transmitted to the switch element TG5, such that the switch circuit 103 is turned off. On the other hand, the voltage signal VG7_2 having the voltage level VGL is transmitted to the switch element TG7, such that the switch circuit 104 is turned on to receive the input voltage signal VIN.

In some embodiments, the switch element T3 is configured to reduce the voltage difference VG_d5 between the nodes N3_1 and D3, and is configured to reduce the voltage difference VG_d6 between the nodes D3 and N3_6. When the switch circuit 103 is turned off, the output voltage signal VO1_2 is terminated at the node N3_1. At this moment, each of a voltage differences VG_d5 and VG_d6 has a voltage level lower than the voltage level VL. When the switch circuit 103 is turned off, the voltage signals VG5_2 has the voltage level VH, the voltage signal VG6_2 has the voltage level VL, and the voltage signal VG6_1 has the voltage level VGL. The switch element T3 is turned on by receiving the voltage signal VT3 having the voltage level VH. In response to the switch element T3 is turned on, the node voltage signal VD3 has the voltage level VL.

On the other hand, in condition CND1, the switch circuit 104 is turned on, such that the testing circuit 120 provides the output voltage signal VO2_2 to the switch element TG7 through the node N4_1. The switch element TG7 transmits the output voltage signal VO2_2 through the switch element TG8 to generate the output voltage signal VOUT at the node N4_6. The output circuit 130 is configured to receive the output voltage signal VOUT from the node N4_6.

In some embodiments, in response to the switch circuit 104 being turned on, each of the voltage signals VG7_1 and VG8_1 has the voltage level VL, and the voltage signal VG6_2 has the voltage level VGL. At this moment, the circuit element T4 is turned off by receiving the voltage signal VT4 having the voltage level VL.

Referring to FIG. 3A to FIG. 4B, in condition CND2, the voltage signal VG5_1 having the voltage level VH is transmitted to the switch element TG5, such that the switch circuit 103 is turned on to receive the output voltage signal VO1_2. On the other hand, the voltages signal VG7_2 having the voltage level VH is transmitted to the switch element TG7, such that the switch circuit 104 is turned off.

In some embodiments, the switch element T4 is configured to reduce the voltage difference VG_d7 between the nodes N4_1 and D4, and is configured to reduce the voltage difference VG_d8 between the nodes D4 and N4_6. When the switch circuit 104 is turned off, the output voltage signal VO2_2 is terminated at the node N4_1. At this moment, each of a voltage differences VG_d7 and VG_d8 has a voltage level lower than a difference between the voltage levels VH and VL. When the switch circuit 104 is turned off, each of the voltage signals VG8_1 and VG8_2 has the voltage level VL, and the voltage signal VG7_1 has the voltage level VGL. The voltage signal VT4 has the voltage level VGL, such that the switch element T4 is turned on. In response to the switch element T4 is turned on, the node voltage signal VD4 has the voltage level VL.

On the other hand, in condition CND2, the switch circuit 103 is turned on, such that the testing circuit 120 provides the output voltage signal VO1_2 to the switch element TG5 through the node N3_1. The switch element TG5 transmits the output voltage signal VO1_2 through the switch element TG6 to generate the output voltage signal VOUT at the node N3_6. The output circuit 130 is configured to receive the output voltage signal VOUT from the node N3_6.

In some embodiments, in response to the switch circuit 103 is turned on, each of the voltage signals VG5_2 and VG5_2 has the voltage level VL, and the voltage signal VG6_1 has the voltage level VH. At this moment, the voltage signal VT3 has the voltage level VL, such that the switch element T3 is turned off.

Referring to FIG. 3A to FIG. 4B, in condition CND3, the control circuit 103_1 transmits the voltage signal VG5_1 having the voltage level VL to the switch element TG5, such that the switch circuit 103 is turned off. The control circuit 104_1 transmits the voltage signal VG7_2 having the voltage level VL to the switch element TG7, such that the switch circuit 104 is turned off. At this moment, in response to each of the switch circuits 103 and 104 being turned off, the output voltage signals VO1_2 and VO2_2 is terminated at the nodes N3_1 and N4_1, respectively.

In some approaches, a switch circuit provides output voltage signal to an output circuit. However, voltage differences between nodes of the switch circuit are high. As a result, when the output circuit is a core device, the core device and switch elements in the switch circuit are damaged by those high voltage differences.

Compared to above approaches, in some embodiments of presented disclosure, the switch element T3 is turned on to secure that each of the voltage differences VG_d5 and VG_d6 has a voltage level lower than the voltage level VL. The switch element T4 is turned on to secure that each of the voltage differences VG_d7 and VG_d8 has a voltage level lower than the difference between the voltage levels VH and VL. Accordingly, voltage levels of the output voltage signal VOUT provided by the switch circuits 103 and 104 is low. As a result, the switch elements TG5, TG6, TG7, and TG8 are protected by those low voltage differences.

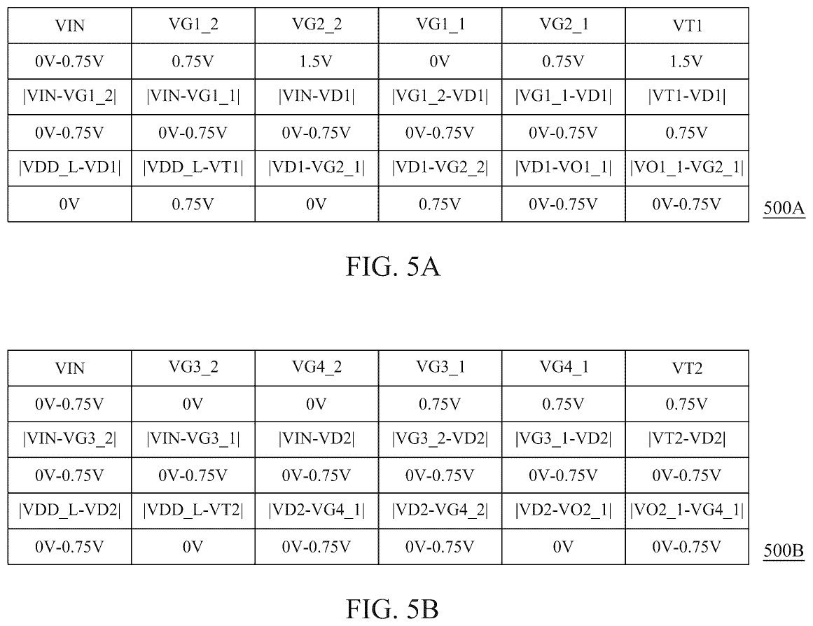

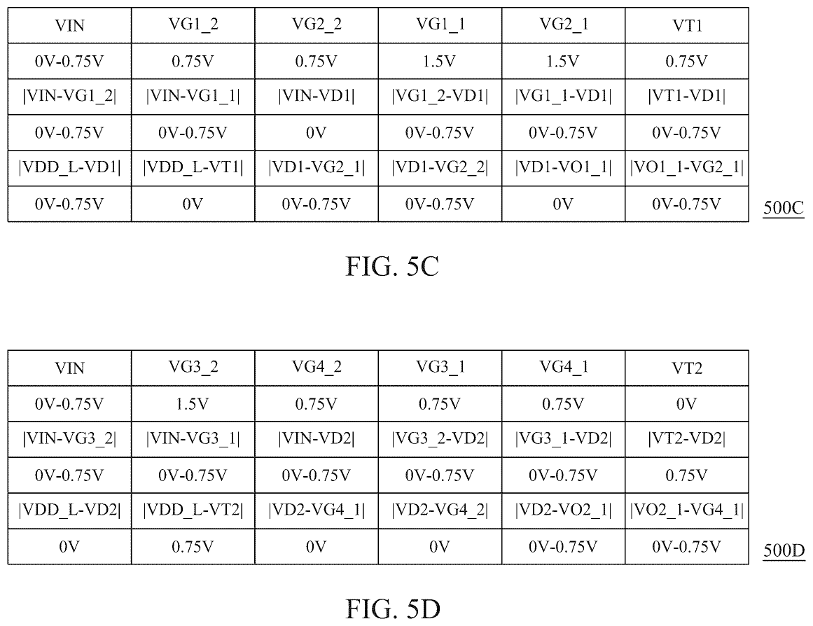

FIG. 5A is a table 500A of voltage differences of the switch circuit 101 shown in FIG. 2A, illustrated in accordance with some embodiments of the presented disclosure. Similar to the switch circuit 101, in some embodiments, the switch circuit 103 in FIG. 2B also has the configuration shown in the table 500A.

In some embodiments, the table 500A is an example corresponding to the condition CND1. The table 500A shows absolute values of the voltage differences of the switch circuit 101. In the embodiment shown in the table 500A, the voltage level VGL is 0 volt, the voltage level VL is 0.75 volt, and the voltage level VH is 1.5 volt; however, the presented disclosure is not limited to the voltage values mentioned herein.

In the condition CND1, the voltage signal VT1 has the voltage level VH, such that the circuit element T1 is turned on. In response to the switch circuit 101 being turned off, each of the voltage signals VG1_2 and VG2_1 has the voltage level VL, the voltage signal VG2_2 has the voltage level VH, and the voltage signal VG1_1 has the voltage level VGL.

As illustratively shown in FIG. 5A, an absolute value |VIN−VG1_2| is an absolute value of a voltage difference between the voltage signals VIN and VG1_2. An absolute value |VIN3−VG1_1| is an absolute value of a voltage difference between the voltage signals VIN and VG1_1. An absolute value |VIN−VD1| is an absolute value of a voltage difference between the voltage signal VIN and the node voltage signal VD1. An absolute value |VG1_2−VD1| is an absolute value of a voltage difference between the voltage signal VG1_2 and the node voltage signal VD1. An absolute value |VG1_1−VD1| is an absolute value of a voltage difference between the voltage signal VG1_1 and the node voltage signal VD1. An absolute value |VT1−VD1| is an absolute value of a voltage difference between the voltage signal VT1 and the node voltage signal VD1. An absolute value |VDD_L−VD1| is an absolute value of a voltage difference between the voltage signal VDD_L and the node voltage signal VD1. An absolute value |VDD_L−VT1| is an absolute value of a voltage difference between the voltage signals VDD_L and VT1. An absolute value |VD1−VG2_1| is an absolute value of a voltage difference between the node voltage signal VD1 and the voltage signal VG2_1. An absolute value |VD1−VG2_2| is an absolute value of a voltage difference between the node voltage signal VD1 and the voltage signal VG2_2. An absolute value |VD1−VG2_1| is an absolute value of a voltage difference between the node voltage signal VD1 and the output voltage signal VO1_1. An absolute value |VO1_1−VG2_1| is an absolute value of a voltage difference between the output voltage signal VO1_1 and the voltage signal VG2_1.

In the condition CND1, the absolute value |VIN−VG1_2| is between the voltage levels VGL and VL. The absolute value |VIN−VG1_1| is between the voltage levels VGL to VL. The absolute value |VIN−VD1| is between the voltage levels VGL to VL. The absolute value |VG1_2−VD1| is between the voltage levels VGL and VL. The absolute value |VG1_1−VD1| is between the voltage levels VGL and VL. The absolute value |VT1−VD1| has the voltage level VL. The absolute value |VDD_L−VD1| has the voltage level VGL. The absolute value |VDD_L−VT1| has the voltage level VL. Regarding the voltage differences between the input voltage signal VIN and the node voltage signal VD1 are lower than the voltage level VL, the switch element TG1 is protected from high voltage differences.

In the condition CND1, the absolute value |VD1−VG2_1| has the voltage level VGL. The absolute value |VD1−VG2_2| has the voltage level VL. The absolute value |VD1−VO1_1| is between the voltage levels VGL and VL. The absolute value |VO1_1−VG2_1| is between the voltage levels VGL and VL. Regarding the voltage differences between the node voltage signal VD1 and the output voltage signal VO1_1 are lower than the voltage level VL, the switch element TG2 is protected from high voltage differences.

In some embodiments, the voltage differences shown in table 500A remain the same when applying the table 500A to the switch circuit 103. The differences of applying the table 500A to the switch circuit 103 compared to the switch circuit 101 are replacing the voltage signals VG1_2, VG2_2, VG1_1, VG2_1, VT1, VD1, and VO1_1 by the voltage signals VG5_2, VG6_2, VG5_1, VG6_1, VT3, VD3, and VOUT, respectively.

FIG. 5B is a table 500B of voltage differences of the switch circuit 102 shown in FIG. 2A, illustrated in accordance with some embodiments of the presented disclosure. Similar to the switch circuit 102, in some embodiments, the switch circuit 104 in FIG. 2B also has the configuration shown in the table 500B.

In some embodiments, the table 500B is an example corresponding to the condition CND1. The table 500B shows absolute values of the voltage differences of the switch circuits 102.

In the condition CND1, the voltage signal VT2 has the voltage level VL, such that the circuit element T2 is turned off. Each of the voltage signals VG3_2 and VG4_2 has the voltage level VGL. Each of the voltage signals VG3_1 and VG4_1 has the voltage level VL.

As illustratively shown in FIG. 5A, an absolute value |VIN−VG3_2| is an absolute value of a voltage difference between the voltage signals VIN and VG3_2. An absolute value |VIN−VG3_1| is an absolute value of a voltage difference between the voltage signals VIN and VG3_1. An absolute value |VIN−VD2| is an absolute value of a voltage difference between the voltage signal VIN and the node voltage signal VD1. An absolute value |VG3_2−VD2| is an absolute value of a voltage difference between the voltage signal VG3_2 and the node voltage signal VD2. An absolute value |VG3_1-VD2| is an absolute value of a voltage difference between the voltage signal VG3_1 and the node voltage signal VD2. An absolute value |VT2−VD2| is an absolute value of a voltage difference between the voltage signal VT2 and the node voltage signal VD2. An absolute value |VDD_L−VD2| is an absolute value of a voltage difference between the voltage signal VDD_L and the node voltage signal VD2. An absolute value |VDD_L−VT2| is an absolute value of a voltage difference between the voltage signals VDD_L and VT2. An absolute value |VD2−VG4_1| is an absolute value of a voltage difference between the node voltage signal VD2 and the voltage signal VG4_1. An absolute value |VD2−VG4_2| is an absolute value of a voltage difference between the node voltage signal VD1 and the voltage signal VG4_2. An absolute value |VD2−VG4_1| is an absolute value of a voltage difference between the node voltage signal VD2 and the output voltage signal VO2_1. An absolute value |VO2_1−VG4_1| is an absolute value of a voltage difference between the output voltage signal VO2_1 and the voltage signal VG4_1.

In the condition CND1, the absolute value |VIN−VG3_2| is between the voltage levels VGL and VL. The absolute value |VIN−VG3_1| is between the voltage levels VGL to VL. The absolute value |VIN−VD2| is between the voltage levels VGL to VL. The absolute value |VG3_2−VD2| is between the voltage levels VGL and VL. The absolute value |VG3_1−VD2| is between the voltage levels VGL and VL. The absolute value |VT2-VD2| is between the voltage levels VGL and VL. The absolute value |VDD_L−VD2| is between the voltage levels VGL and VL. The absolute value |VDD_L−VT2| has the voltage level VGL. The absolute value |VD2−VG2_1| is between the voltage levels VGL and VL. Regarding the voltage differences between the input voltage signal VIN and the node voltage signal VD2 are lower than the voltage level VL, the switch element TG3 is protected from high voltage differences.

In the condition CND1, the absolute value |VD2−VG4_2| is between the voltage levels VGL and VL. The absolute value |VD2−VO2_1| has the voltage level VGL. The absolute value |VO2_1−VG4_1| is between the voltage levels VGL and VL. Regarding the voltage differences between the node voltage signal VD2 and the output voltage signal VO2_1 are lower than the voltage level VL, the switch element TG3 is protected from high voltage differences.

In some embodiments, the voltage differences shown in table 500B remain the same when applying the table 500B to the switch circuit 104. The differences of applying the table 500B to the switch circuit 104 compared to the switch circuit 102 are replacing the voltage signals VG3_2, VG4_2, VG3_1, VG4_1, VT2, VD2, and VO2_1 by the voltage signals VG7_2, VG8_2, VG7_1, VG8_1, VT4, VD4, and VOUT, respectively.

FIG. 5C is a table 500C of voltage differences of the switch circuit 101 shown in FIG. 2A, illustrated in accordance with some embodiments of the presented disclosure. Similar to the switch circuit 101, in some embodiments, the switch circuit 103 in FIG. 2B also has the configuration shown in the table 500C.

In some embodiments, the table 500C is an example corresponding to the condition CND2. The table 500C shows absolute values of the voltage differences of the switch circuits 101.

In the condition CND2, the voltage signal VT1 has the voltage level VL, such that the circuit element T1 is turned off. Each of the voltage signals VG1_2 and VG2_2 has the voltage level VL. Each of the voltage signals VG1_1 and VG2_1 has the voltage level VH.

In the condition CND2, the absolute value |VIN−VG1_2| is between the voltage levels VGL and VL. The absolute value |VIN−VG1_1| is between the voltage levels VGL to VL. The absolute value |VIN−VD1| has the voltage level VGL. The absolute value |VG1_2−VD1| is between the voltage levels VGL and VL. The absolute value |VG1_1−VD1| is between the voltage levels VGL and VL. The absolute value |VT1−VD1| is between the voltage levels VGL and VL. The absolute value |VDD_L−VD1| is between the voltage levels VGL and VL. The absolute value |VDD_L−VT1| has the voltage level VGL. Regarding the voltage differences between the input voltage signal VIN and the node voltage signal VD1 are lower than the difference between the voltage levels VH and VL, the switch element TG1 is protected from high voltage differences.

In the condition CND2, the absolute value |VD1−VG2_1| is between the voltage levels VGL and VL. The absolute value |VD1−VG2_2| is between the voltage levels VGL and VL. The absolute value |VD1−VO1_1| has a value of VGL. The absolute value |VO1_1−VG2_1| is between the voltage levels VGL and VL. Regarding the voltage differences between the node voltage signal VD1 and the output voltage signal VO1_1 are lower than the difference between the voltage levels VH and VL, the switch element TG2 is protected from high voltage differences.

In some embodiments, the voltage differences shown in table 500C remain the same when applying the table 500C to the switch circuit 103. The differences of applying the table 500C to the switch circuit 103 compared to the switch circuit 101 are replacing the voltage signals VG1_2, VG2_2, VG1_1, VG2_1, VT1, VD1, and VO1_1 by the voltage signals VG5_2, VG6_2, VG5_1, VG6_1, VT3, VD3, and VOUT, respectively.

FIG. 5D is a table 500D of voltage differences of the switch circuit 102 shown in FIG. 2A, illustrated in accordance with some embodiments of the presented disclosure. Similar to the switch circuit 102, in some embodiments, the switch circuit 104 in FIG. 2B also has the configuration shown in the table 500D.

In some embodiments, the table 500D shows an example corresponding to the condition CND2. The table 500D shows absolute values of the voltage differences of the switch circuits 102.

In the condition CND2, the voltage signal VT2 has the voltage level VGL, such that the circuit element T2 is turned on. The voltage signal VG3_2 has the voltage level VH. Each of the voltage signals VG3_1, VG4_1, and VG4_2 has the voltage level VL.

In the condition CND2, the absolute value |VIN−VG3_2| is between the voltage levels VGL and VL. The absolute value |VIN−VG3_1| is between the voltage levels VGL to VL. The absolute value |VIN−VD2| is between the voltage levels VGL to VL. The absolute value |VG3_2−VD2| is between the voltage levels VGL and VL. The absolute value |VG3_1−VD2| is between the voltage levels VGL and VL. The absolute value |VT2−VD2| has the voltage level VGL. The absolute value |VDD_L−VD2| has the voltage level VGL. The absolute value |VDD_L−VT2| has the voltage level VL. Regarding the voltage differences between the input voltage signal VIN and the node voltage signal VD2 are lower than the voltage difference between the voltage levels VH and VL, the switch element TG3 is protected from high voltage differences.

In the condition CND2, the absolute value |VD2−VG4_1| has a value of VGL. The absolute value |VD2−VG4_2| has the voltage level VGL. The absolute value |VD2−VO2_1| is between the voltage levels VGL and VL. The absolute value |VO2_1−VG4_1| is between the voltage levels VGL and VL. Regarding the voltage differences between the node voltage signal VD2 and the output voltage signal VO2_1 are lower than the difference between the voltage levels VH and VL, the switch element TG4 is protected from high voltage differences.

In some embodiments, the voltage differences shown in table 500D remain the same when applying the table 500D to the switch circuit 104. The differences of applying the table 500D to the switch circuit 104 compared to the switch circuit 102 are replacing the voltage signals VG3_2, VG4_2, VG3_1, VG4_1, VT2, VD2, and VO2_1 by the voltage signals VG7_2, VG8_2, VG7_1, VG8_1, VT4, VD4, and VOUT, respectively.

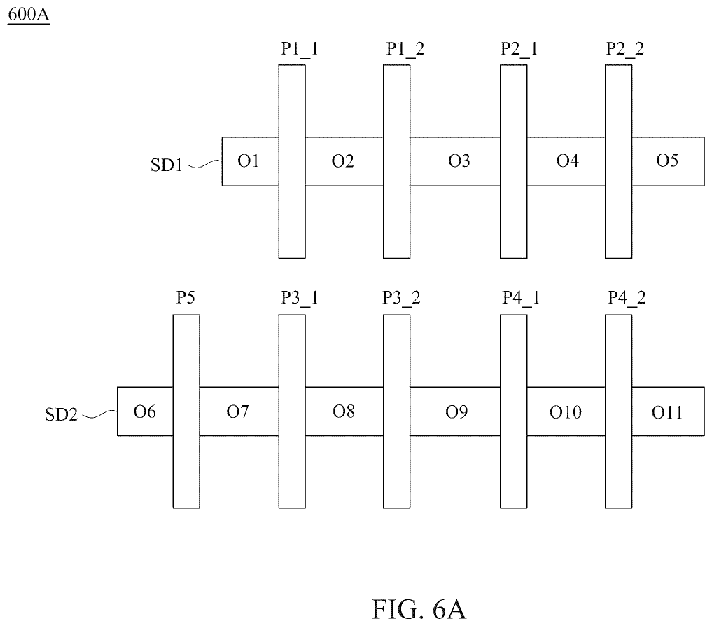

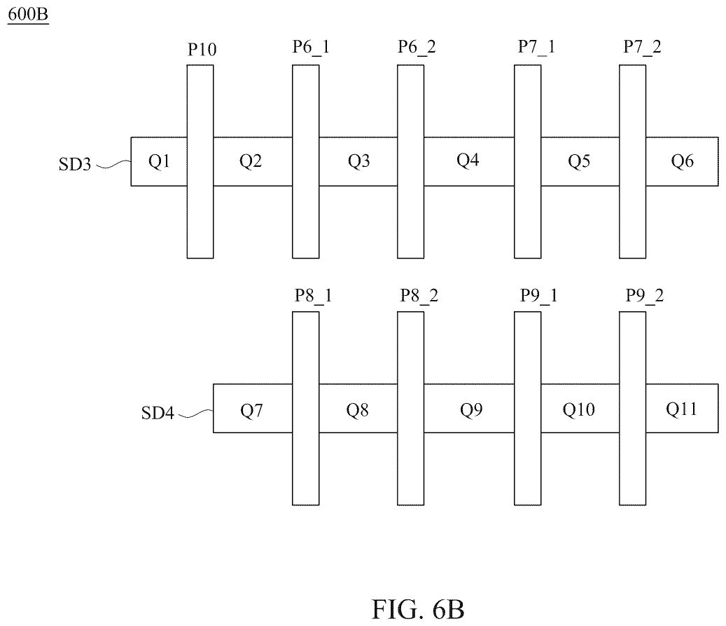

FIG. 6A is a layout structure 600A of the switch circuits, illustrated in accordance with some embodiments of the presented disclosure. In some embodiments, the layout structure 600A corresponds to the switch circuit 101 shown in FIG. 2A and the switch circuit 103 shown in FIG. 2B.

As illustratively shown in FIG. 6A, the layout structure 600A includes a conductive passes SD1 and SD2, gate structures P1_1, P1_2, P2_1, P2_2, P3_1, P3_2, P4_1, P4_2, and P5. In some embodiments, the layout structure 600A further includes multiple portions O1-O11. The portions O1-O5 are formed through separating the conductive pass SD1 by the gate structures P1_1, P1_2, P2_1, and P2_2. The portions O6-O11 are formed through separating the conductive pass SD2 by the gate structures P3_1, P3_2, P4_1, P4_2, and P5.

Refer to FIG. 6A and FIG. 2A, the switch circuit 101 is implemented by the layout structure 600A in practical application. However, the layout structure of the switch circuit 101 is not limited to the layout structure 600A of the presented disclosure.

In some embodiments, the gate structures P1_1 and P1_2 correspond to a gate terminal of the switch element TG1 connecting to the node N1_3. The gate structures P3_1 and P3_2 correspond to a gate terminal of the switch element TG1 connecting to the node N1_2. The gate structures P2_1 and P2_2 correspond to a gate terminal of the switch element TG2 connecting to the node N1_5. The gate structures P4_1 and P4_2 correspond to a gate terminal of the switch element TG2 connecting to the node N1_4. The gate structure P5 corresponds to a gate terminal of the circuit element T1 configured to receive the voltage signal VT1.

In some embodiments, each of the portions O1, O3, O5, O7, O9, and O11 corresponds to the node D1 of the switch circuit 101. Each of the portions O2 and O8 corresponds to the node N1_1 configured to receive the input voltage signal VIN. Each of the portions O4 and O10 corresponds to the node N1_6 configured to generate the output voltage signal VO1_1. The portion O6 corresponds to a terminal of the circuit element T1 configured to receive the voltage signal VDD_L.

Refer to FIG. 6A and FIG. 2B, the switch circuit 103 can also be implemented by the layout structure 600A in practical application. However, the layout structure of the switch circuit 103 is not limited to the layout structure 600A of the presented disclosure.

In some embodiments, the gate structures P1_1 and P1_2 correspond to a gate terminal of the switch element TG5 connecting to the node N3_3. The gate structures P3_1 and P3_2 correspond to a gate terminal of the switch element TG5 connecting to the node N3_2. The gate structures P2_1 and P2_2 correspond to a gate terminal of the switch element TG6 connecting to the node N3_5. The gate structures P4_1 and P4_2 correspond to a gate terminal of the switch element TG6 connecting to the node N3_4. The gate structure P5 corresponds to a gate terminal of the circuit element T3 configured to receive the voltage signal VT3.

In some embodiments, each of the portions O1, O3, O5, O7, O9, and O11 corresponds to the node D3 of the switch circuit 103. Each of the portions O2 and O8 corresponds to the node N3_1 configured to receive the output voltage signal VO1_2. Each of the portions O4 and O10 corresponds to the node N3_6 configured to generate the output voltage signal VOUT. The portion O6 corresponds to a terminal of the circuit element T3 configured to receive the voltage signal VDD_L.

FIG. 6B is a layout structure 600B of the switch circuits, illustrated in accordance with some embodiments of the disclosure. In some embodiments, the layout structure 600B corresponds to the switch circuit 102 shown in FIG. 2A and the switch circuit 104 shown in FIG. 2B.

As illustratively shown in FIG. 6B, the layout structure 600B includes a conductive passes SD3 and SD4, gate structures P6_1, P6_2, P7_1, P7_2, P8_1, P8_2, P9_1, P9_2, and P10. In some embodiments, the layout structure 600B further includes multiple portions Q1-Q11. The portions Q1-Q6 are formed through separating the conductive pass SD3 by the gate structures P6_1, P6_2, P7_1, P7_2, and P10. The portions Q7-Q11 are formed through separating the conductive pass SD4 by the gate structures P8_1, P8_2, P9_1, and P9_2.

Refer to FIG. 6B and FIG. 2B, the switch circuit 102 can be implemented by the layout structure 600B in practical application. However, the layout structure of the switch circuit 102 is not limited to the layout structure 600B of the presented disclosure.

In some embodiments, the gate structures P6_1 and P6_2 correspond to a gate terminal of the switch element TG3 connecting to the node N2_3. The gate structures P8_1 and P8_2 correspond to a gate terminal of the switch element TG3 connecting to the node N2_2. The gate structures P7_1 and P7_2 correspond to a gate terminal of the switch element TG4 connecting to the node N2_5. The gate structures P9_1 and P9_2 correspond to a gate terminal of the switch element TG4 connecting to the node N2_4. The gate structure P10 corresponds to a gate terminal of the circuit element T2 configured to receive the voltage signal VT2.

In some embodiments, each of the portions Q2, Q4, Q6, Q7, Q9, and Q11 corresponds to the node D2 of the switch circuit 102. Each of the portions Q3 and Q8 corresponds to the node N2_1 configured to receive the input voltage signal VIN. Each of the portions Q5 and Q10 corresponds to the node N2_6 configured to generate the output voltage signal VO2_1. The portion Q1 corresponds to a terminal of the circuit element T2 configured to receive the voltage signal VDD_L.

Refer to FIG. 6B and FIG. 2B, the switch circuit 104 can also be implemented by the layout structure 600B in practical application. However, the layout structure of the switch circuit 104 is not limited to the layout structure 600B of the disclosure.

In some embodiments, the gate structures P6_1 and P6_2 correspond to a gate terminal of the switch element TG7 connecting to the node N4_3. The gate structures P8_1 and P8_2 correspond to a gate terminal of the switch element TG7 connecting to the node N4_2. The gate structures P7_1 and P7_2 correspond to a gate terminal of the switch element TG8 connecting to the node N4_5. The gate structures P9_1 and P9_2 correspond to a gate terminal of the switch element TG8 connecting to the node N4_4. The gate structure P10 corresponds to a gate terminal of the circuit element T4 configured to receive the voltage signal VT4.

In some embodiments, each of the portions Q2, Q4, Q6, Q7, Q9, and Q11 corresponds to the node D4 of the switch circuit 104. Each of the portions Q3 and Q8 corresponds to the node N4_1 configured to receive the output voltage signal VO2_2. Each of the portions Q5 and Q10 corresponds to the node N4_6 configured to generate the output voltage signal VOUT. The portion Q1 corresponds to a terminal of the circuit element T4 configured to receive the voltage signal VDD_L.

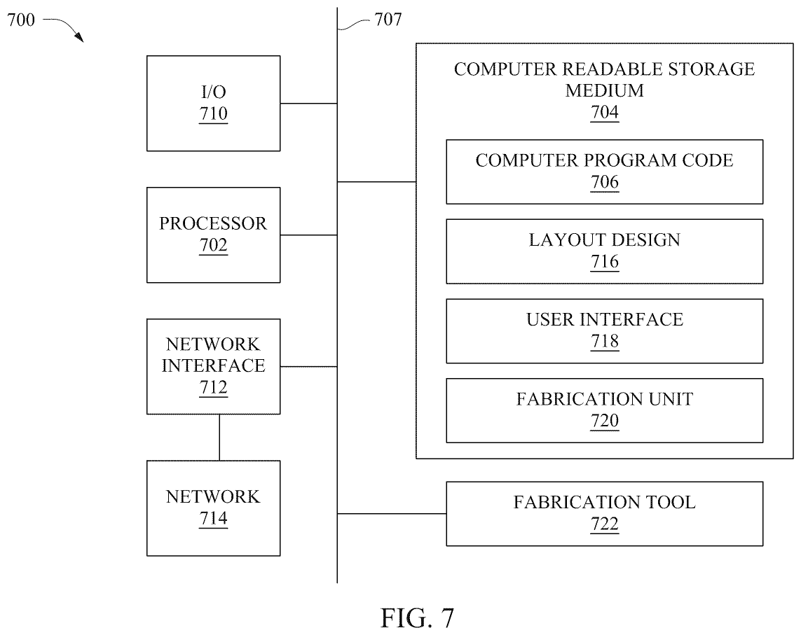

FIG. 7 is a schematic view of a system 700 for designing and manufacturing at least one of the semiconductor devices described herein, illustrated in accordance with some embodiments of the present disclosure. The system 700 generates or places one or more IC layout designs corresponding to at least one of the semiconductor devices described herein, as described herein. In some embodiments, the system 700 manufactures one or more semiconductor devices based on the one or more IC layout designs, as described herein. The system 700 includes a hardware processor 702 and a non-transitory, computer readable storage medium 704 encoded with, e.g., storing, the computer program code 706, e.g., a set of executable instructions. The computer readable storage medium 704 is configured for interfacing with manufacturing machines for producing the semiconductor device. The processor 702 is electrically coupled to the computer readable storage medium 704 by a bus 707. The processor 702 is also electrically coupled to an I/O interface 710 by the bus 707. A network interface 712 is also electrically connected to the processor 702 by the bus 707. Network interface 712 is connected to a network 714, so that the processor 702 and the computer readable storage medium 704 are capable of connecting to external elements via network 714. The processor 702 is configured to execute the computer program code 706 encoded in the computer readable storage medium 704 in order to cause the system 700 designing and manufacturing at least one of the semiconductor devices described herein.

In some embodiments, the processor 702 is a central processing unit (CPU), a multi-processor, a distributed processing system, an application specific integrated circuit (ASIC), and/or a suitable processing unit.

In some embodiments, the computer readable storage medium 704 is an electronic, magnetic, optical, electromagnetic, infrared, and/or a semiconductor system (or apparatus or device). For example, the computer readable storage medium 704 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 704 includes a compact disk-read only memory (CD-ROM), a compact disk-read/write (CD-R/W), and/or a digital video disc (DVD).

In some embodiments, the storage medium 704 also stores information needed for designing and manufacturing at least one of the semiconductor devices described herein, such as layout design 716, user interface 717, fabrication unit 720, and/or a set of executable instructions to designing and manufacturing at least one of the semiconductor devices described herein.

In some embodiments, the storage medium 704 stores instructions (e.g., the computer program code 706) for interfacing with manufacturing machines. The instructions (e.g., the computer program code 706) enable the processor 702 to generate manufacturing instructions readable by the manufacturing machines to effectively implement the semiconductor devices described herein.

The system 700 includes the I/O interface 710. The I/O interface 710 is coupled to external circuitry. In some embodiments, the I/O interface 710 includes a keyboard, keypad, mouse, trackball, trackpad, and/or cursor direction keys for communicating information and commands to the processor 702.

The system 700 also includes the network interface 712 coupled to the processor 702. The network interface 712 allows the system 700 to communicate with the network 714, to which one or more other computer systems are connected. The network interface 712 includes wireless network interfaces such as BLUETOOTH, WIFI, WIMAX, GPRS, or WCDMA; or wired network interface such as ETHERNET, USB, or IEEE-13154. In some embodiments, the designing and manufacturing of at least one of the semiconductor devices described herein is implemented in two or more systems 700, and information such as layout design, user interface and fabrication unit are exchanged between different systems 700 by the network 714.

The system 700 is configured to receive information related to a layout design through the I/O interface 710 or network interface 712. The information is transferred to the processor 702 by the bus 707 to determine a layout design for producing an IC. The layout design is then stored in the computer readable medium 704 as the layout design 716. The system 700 is configured to receive information related to a user interface through the I/O interface 710 or network interface 712. The information is stored in the computer readable medium 704 as the user interface 717. The system 700 is configured to receive information related to a fabrication unit through the I/O interface 710 or network interface 712. The information is stored in the computer readable medium 704 as the fabrication unit 720. In some embodiments, the fabrication unit 720 includes fabrication information utilized by the system 700.

In some embodiments, the designing and manufacturing of at least one of the semiconductor devices described herein is implemented as a standalone software application for execution by a processor. In some embodiments, the designing and manufacturing of at least one of the semiconductor devices described herein is implemented as a software application that is a part of an additional software application. In some embodiments, the designing and manufacturing of at least one of the semiconductor devices described herein is implemented as a plug-in to a software application. In some embodiments, the designing and manufacturing of at least one of the semiconductor devices described herein is implemented as a software application that is a portion of an EDA tool. In some embodiments, the designing and manufacturing of at least one of the semiconductor devices described herein is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, at least one of the semiconductor devices described herein is implemented by a manufacturing device to manufacture an integrated circuit using a set of masks manufactured based on one or more layout designs generated by the system 700. In some embodiments, the system 700 includes a manufacturing device (e.g., fabrication tool 722) to manufacture an integrated circuit using a set of masks manufactured based on one or more layout designs of the present disclosure.

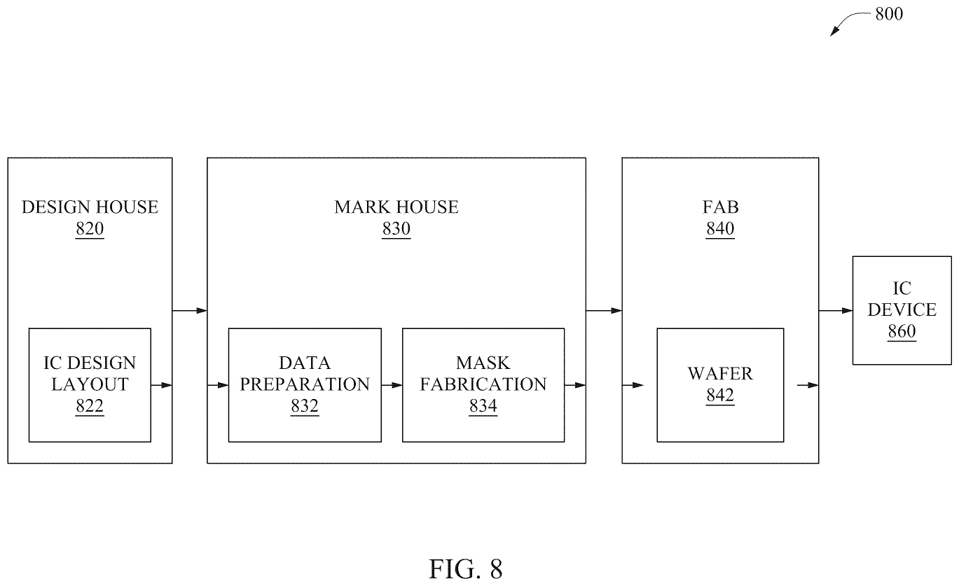

FIG. 8 is a block diagram of an integrated circuit (IC)/semiconductor device manufacturing system 800, and an IC manufacturing flow associated therewith, illustrated in accordance with some embodiments of the present disclosure.

In FIG. 8, the IC manufacturing system 800 includes entities, such as a design house 820, a mask house 830, and an IC manufacturer/fabricator (“fab”) 840, that interact with one another in the design, development, and manufacturing cycles and/or services related to manufacturing an IC device (semiconductor device) 860 including at least one of the semiconductor devices described herein. The entities in system 800 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 820, mask house 830, and IC fab 840 is owned by a single company. In some embodiments, two or more of design house 820, mask house 830, and IC fab 840 coexist in a common facility and use common resources.

The design house (or design team) 820 generates an IC design layout 822. The IC design layout 822 includes various geometrical patterns designed for the IC device 860. The geometrical patterns correspond to patterns of metal, oxide, or semiconductor layers that make up the various components of the IC device 860 to be fabricated. The various layers combine to form various IC features. For example, a portion of the IC design layout 822 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 820 implements a proper design procedure to form the IC design layout 822. The design procedure includes one or more of logic design, physical design or place and route. The IC design layout 822 is presented in one or more data files having information of the geometrical patterns. For example, the IC design layout 822 can be expressed in a GDSII file format or DFII file format.

The mask house 830 includes mask data preparation 832 and mask fabrication 834. The mask house 830 uses the IC design layout 822 to manufacture one or more masks to be used for fabricating the various layers of the IC device 860 according to the IC design layout 822. The mask house 830 performs the mask data preparation 832, where the IC design layout 822 is translated into a representative data file (“RDF”). The mask data preparation 832 provides the RDF to the mask fabrication 834. The mask fabrication 834 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 832 to comply with particular characteristics of the mask writer and/or requirements of the IC fab 840. In FIG. 8, the mask data preparation 832 and mask fabrication 834 are illustrated as separate elements. In some embodiments, the mask data preparation 832 and mask fabrication 834 can be collectively referred to as mask data preparation.

In some embodiments, the mask data preparation 832 includes optical proximity correction (OPC) which uses lithography enhancement techniques to compensate for image errors, such as those that can arise from diffraction, interference, other process effects and the like. OPC adjusts the IC design layout 822. In some embodiments, the mask data preparation 832 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 832 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 834, which may undo part of the modifications performed by OPC in order to meet mask creation rules.

In some embodiments, the mask data preparation 832 includes lithography process checking (LPC) that simulates processing that will be implemented by the IC fab 840 to fabricate the IC device 860. LPC simulates this processing based on the IC design layout 822 to create a simulated manufactured device, such as the IC device 860. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 822.

It should be understood that the herein description of the mask data preparation 832 has been simplified for the purposes of clarity. In some embodiments, the mask data preparation 832 includes additional features such as a logic operation (LOP) to modify the IC design layout according to manufacturing rules. Additionally, the processes applied to the IC design layout 822 during the mask data preparation 832 may be executed in a variety of different orders.

After the mask data preparation 832 and during mask fabrication 834, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 834 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 840 is an IC fabrication entity that includes one or more manufacturing facilities for the fabrication of a variety of different IC products. In some embodiments, the IC fab 840 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 840 uses the mask (or masks) fabricated by the mask house 830 to fabricate the IC device 860. Thus, the IC fab 840 at least indirectly uses the IC design layout 822 to fabricate the IC device 860. In some embodiments, a semiconductor wafer is fabricated by the IC fab 840 using the mask (or masks) to form the IC device 860. The semiconductor wafer 842 includes a silicon substrate or other proper substrate having material layers formed thereon. Semiconductor wafer further includes one or more of various doped regions, dielectric features, multilevel interconnects, and the like (formed at subsequent manufacturing steps).

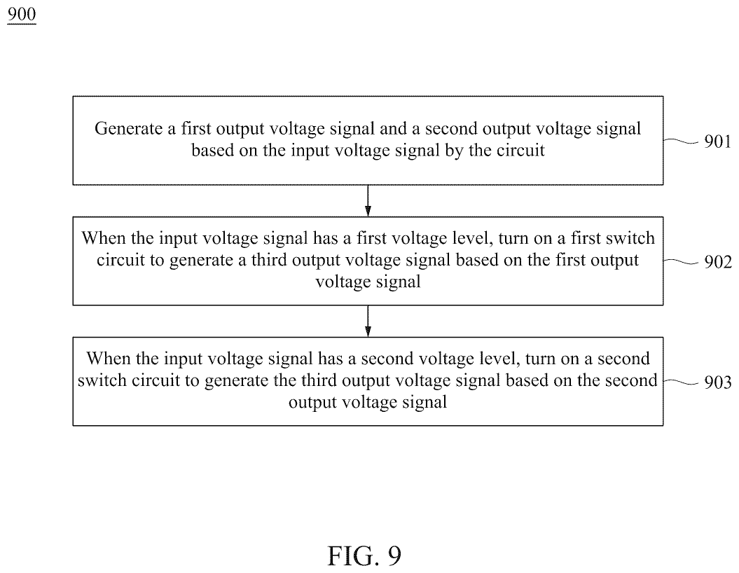

FIG. 9 is a flow diagram of a method 900 of operating the semiconductor device 100, illustrated in accordance with some embodiments of the disclosure. As shown in FIG. 9, the method 900 includes operations 901-903.

At operation 901, generate a first output voltage signal and a second output voltage signal based on the input voltage signal by the circuit.

For example, the testing circuit 110 generates the output voltage signals VO1_2 and VO2_2 based on the input voltage signal VIN. The semiconductor device 100 continues to the operation 902 after the operation 901.

At operation 902, when the input voltage signal has a first voltage level, turn on a first switch circuit to generate a third output voltage signal based on the first output voltage signal.

For example, when the input voltage signal VIN has the voltage level VH, turn on the switch circuit 103 to generate the output voltage signal VOUT based on the output voltage signal VO1_2. The semiconductor device 100 continues to the operation 903 after the operation 902.

At operation 903, when the input voltage signal has a second voltage level, turn on a second switch circuit to generate the third output voltage signal based on the second output voltage signal.

For example, when the input voltage signal VIN has the voltage level VL, turn on the switch circuit 104 to generate the output voltage signal VOUT based on the output voltage signal VO2_2. The semiconductor device 100 completes the method 900 after completing the operation 903.

In some embodiments, the method 900 also comprises receiving a plurality of control signals according to the input voltage signal; and generating a first voltage signal to a first switch element of the first switch circuit according to the plurality of control signals.

For example, the control circuit 103_1 receives the control signals CONT_A, CONT_B, and CONT_C according to the input voltage signal VIN, and generates the voltage signal VG5_1 to the switch element TG5 of the switch circuit 103.

In some embodiments, the method 900 also comprises receiving the plurality of control signals according to the input voltage signal; and generating a second voltage signal to a second switch element of the second switch circuit according to the plurality of control signals.

For example, the control circuit 104_1 receives the control signals CONT_A, CONT_B, and CONT_C according to the input voltage signal VIN, and generates the voltage signal VG7_2 to the switch element TG7 of the switch circuit 104.

Also disclosed is a semiconductor device. The semiconductor device comprises a first switch circuit configured to receive an input voltage signal and provide a first output voltage signal to a circuit; a first control circuit coupled to the first switch circuit, configured to turn on the first switch circuit when the input voltage signal has a first voltage level, and configured to turn off the first switch circuit when the input voltage signal has a second voltage level; a second switch circuit configured to receive the input voltage signal and provide a second output voltage signal to the circuit; and a second control circuit coupled to the second switch circuit, configured to turn on the second switch when the input voltage has the second voltage level, and turn off the second switch when the input voltage has the first voltage level, wherein the first voltage level is different from the second voltage level.

Also disclosed is a semiconductor device. The semiconductor device comprises a first switch circuit configured to receive an input voltage signal and provide a first output voltage signal to a circuit, the first switch circuit comprises a first switch element configured to receive the input voltage signal; a second switch element configured to generate the first output voltage signal, and coupled to the first switch element at a first node; and a third circuit element coupled to the first node, and configured to provide a voltage signal to the first node.

Also disclosed is a method. The method comprises generating a first output voltage signal and a second output voltage signal based on the input voltage signal by the circuit. When the input voltage signal has a first voltage level, turning on a first switch circuit to generate a third output voltage signal based on the first output voltage signal. When the input voltage signal has a second voltage level, turning on a second switch circuit to generate the third output voltage signal based on the second output voltage signal. Wherein the first voltage level is different from the second voltage level.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first switch circuit (101) configured to receive an input voltage signal (VIN), and provide a first output voltage signal (VO1_1) to a circuit (120);
a first control circuit (101_1) coupled to the first switch circuit, configured to turn on the first switch circuit when the input voltage signal has a first voltage level (VINH) (CND2), and configured to turn off the first switch circuit when the input voltage signal has a second voltage level (VINL) (CND1);
a second switch circuit (102) configured to receive the input voltage signal and provide a second output voltage signal (VO2_1) to the circuit; and
a second control circuit (102_1) coupled to the second switch circuit, configured to turn on the second switch when the input voltage has the second voltage level (VINL) (CND1), and turn off the second switch when the input voltage has the first voltage level (VINH) (CND2),
wherein the first voltage level is different from the second voltage level.

2. The semiconductor device of claim 1, wherein the first switch circuit comprising:
a first switch element (TG1) configured to receive the input voltage signal;
a second switch element (TG2) configured to generate the first output voltage signal, and coupled to the first switch element at a first node (D1); and
a third switch element (T1) coupled to the first node, and configured to provide a voltage signal (VDD_L) to the first node.

3. The semiconductor device of claim 1, wherein the second switch circuit comprising:
a fourth switch element (TG3) configured to receive the input voltage signal;
a fifth switch element (TG4) configured to generate the second output voltage signal, and coupled to the fourth switch element at a second node (D2); and
a sixth switch element (T2) coupled to the second node, and configured to provide a voltage signal (VDD_L) to the second node.

4. The semiconductor device of claim 1, further comprising:
a third switch circuit (103) configured to receive a third output voltage signal (VO1_2) and provide a fifth output voltage signal (VOUT) to a load; and
a fourth switch circuit (104) configured to receive a fourth output voltage signal (VO2_2) and provide the fifth output voltage signal to the load,
wherein the third output voltage signal and the fourth output voltage is generated by the circuit according to the first output voltage signal and the second output voltage signal, respectively.

5. The semiconductor device of claim 4, further comprising:
a third control circuit (103_1) coupled to the third switch circuit; and
a fourth control circuit (104_1) coupled to the fourth switch circuit,
wherein when the input voltage signal has the first voltage level (CND2), the third switch circuit is turned on by the third control circuit and the fourth switch circuit is turned off by the fourth control circuit, and
when the input voltage signal has the second voltage level (CND1), the third switch circuit is turned off by the third control circuit and the fourth switch circuit is turned on by the fourth control circuit.

6. The semiconductor device of claim 4, wherein the third switch circuit comprising:
a seventh switch element (TG5) configured to receive the third output voltage signal;
a eighth switch element (TG6) configured to generate the fifth output voltage signal, and coupled to the seventh switch element at a third node (D3); and
a ninth switch element (T3) coupled to the third node, and configured to provide a voltage signal (VDD_L) to the third node.

7. The semiconductor device of claim 4, wherein the fourth switch circuit comprising:
a tenth switch element (TG7) configured to receive the fourth output voltage signal;
an eleventh switch element (TG8) configured to generate the fifth output voltage signal, and coupled to the tenth switch element at a fourth node (D4); and
a twelfth circuit element (T4) coupled to the fourth node, and configured to provide a voltage signal (VDD_L) to the fourth node.

8. The semiconductor device of claim 1, wherein
the first control circuit is configured to generate a first voltage signal (VG1_1) having a third voltage level (VGL) to turn off the first switch circuit, and
the second control circuit is configured to generate a second voltage signal (VG3_2) having the third voltage level to turn on the second switch circuit.

9. The semiconductor device of claim 8, wherein
the first control circuit is configured to generate a first voltage signal (VG1_1) having a fourth voltage level (VH) to turn on the first switch circuit, and
the second control circuit is configured to generate a second voltage signal (VG3_2) having the fourth voltage level to turn off the second switch circuit.

10. The semiconductor device of claim 9, wherein the first voltage level is higher than the second voltage level, and the fourth voltage level is higher than the third voltage level.

11. The semiconductor device of claim 9, wherein the first control circuit comprising:
a ninth switch circuit (S1), a control terminal of the ninth switch circuit configured to receive a first control signal (CONT_A);
a tenth switch circuit (S4) coupled to the ninth switch circuit, a control terminal of the tenth switch circuit configured to receive a second control signal (CONT_B); and
an eleventh switch circuit (S5) coupled to each of the ninth switch circuit and the tenth switch circuit through a fifth node (N_SW), a control terminal of the eleventh switch circuit configured to receive a third control signal (CONT_C),
wherein the first control circuit is coupled to the first switch circuit through the fifth node.

12. The semiconductor device of claim 11, wherein
when the first control signal has the fourth voltage level (VH) and each of the second control signal and the third control signal has a fifth voltage level (VL), each of the first voltage signal and the second voltage signal has the third voltage level (VGL),
when each of the first control signal and the third control signal has the fifth voltage level(VL) and the second control signal has the third voltage level (VGL), each of the first voltage signal and the second voltage signal has the fourth voltage level (VH).

13. A semiconductor device, comprising a first switch circuit (101) configured to receive an input voltage signal (VIN) and provide a first output voltage signal (VO1_1) to a circuit (130), the first switch circuit comprising:
a first switch element (TG1) configured to receive the input voltage signal;
a second switch element (TG2) configured to generate the first output voltage signal, and coupled to the first switch element at a first node (D1); and
a third circuit element (T1) coupled to the first node, and configured to provide a voltage signal (VDD_L) to the first node.

14. The semiconductor device of claim 13, further comprising:
a first control circuit (101_1) coupled to the first switch element,
wherein the first control circuit is configured to generate a first voltage signal (VG1_1) according to a plurality of control signals.

15. The semiconductor device of claim 14, wherein
when the input voltage signal has a first voltage level (VINH), the first control circuit generates the first voltage signal (VG1_1) having a second voltage level(VH) to turn on the first switch circuit, and
when the input voltage signal has a third voltage level (VINL), the first control circuit generates the first voltage signal having a fourth voltage level (VGL) to turn off the first switch circuit.

16. The semiconductor device of claim 15, wherein the first voltage level is higher than the third voltage level and the second voltage level is higher than the fourth voltage level.

17. The semiconductor device of claim 13, further comprising a second switch circuit (102) configured to receive the input voltage signal and provide a second output voltage signal (VO2_1) to the circuit (120), the second switch circuit comprising:
a third switch element (TG3) configured to receive the input voltage signal;
a fourth switch element (TG4) configured to generate the second output voltage signal, and coupled to the third switch element at a second node (D2);
a fifth switch element (T2) coupled to the second node, and configured to provide a voltage signal (VDD_L) to the second node; and
a second control circuit (102_1) coupled to the third switch element,
wherein the second control circuit is configured to generate a second voltage signal according to a plurality of control signals (CONT_A, CONT_B, and CONT_C).

18. The semiconductor device of claim 17, wherein
when the input voltage signal has a fifth voltage level (VINH), the second control circuit generates the second voltage signal (VG2_3) having a sixth voltage level(VH) to turn off the second switch circuit,
when the input voltage signal has a seventh voltage level (VINL), the second control circuit generates the second voltage signal having an eighth voltage level (VGL) to turn on the second switch circuit, and
wherein the fifth voltage level is higher than the seventh voltage level and the sixth voltage level is higher than the eighth voltage level.

19. A method, comprising:
generating a first output voltage signal (VO1_2) and a second output voltage signal (VO2_2) based on a input voltage signal (VIN) by a circuit (130);
when the input voltage signal has a first voltage level (VINH), turning on a first switch circuit (103) to generate a third output voltage signal (VOUT) based on the first output voltage signal (VO1_2); and
when the input voltage signal has a second voltage level (VINL), turning on a second switch circuit (104) to generate the third output voltage signal based on the second output voltage signal (VO2_2),
wherein the first voltage level is different from the second voltage level.

20. The method of claim 19, wherein
turning on the first switch circuit comprising:
receiving a plurality of control signals according to the input voltage signal; and
generating a first voltage signal (VG5_1) to a first switch element (TG5) of the first switch circuit according to the plurality of control signals;
turning on the second switch circuit comprising:
receiving the plurality of control signals according to the input voltage signal; and
generating a second voltage signal (VG7_2) to a second switch element (TG7) of the second switch circuit according to the plurality of control signals, and
wherein the first voltage signal has a voltage level (VH) higher than a voltage level (VGL) of the second voltage signal.
